(19) United States
(12) Patent Application Publication
(10) Pub. No.: US 2026/0291481 A1
(43) Pub. Date: Sep. 24, 2026

(54) SWITCH MATRIX WITH HIGH RADIO FREQUENCY ISOLATION UTILIZING DUAL MECHANICAL MICRO-MEMBRANE ACTUATORS

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/085,854

(22) Filed: Mar. 20, 2025

(51) Int. Cl. H03K 17/00

(52) U.S. Cl. CPC H03K 17/002

(57) ABSTRACT

The technology described herein is directed towards a (e.g., 2×2) mechanical micro-actuator-based RF switch matrix including six switches, that allows non-blocking signal routing between any two available RF ports. In one implementation, there are four single-membrane actuators and two dual-membrane actuators. A crossover design with a tuned permittivity patch provides isolation between intersecting RF lines, allowing simultaneous signal transmission without significant interference. The switch matrix device based on mechanical micro-actuator switches is designed for high isolation between RF transmission paths, including using the crossover and the combination of single and dual-membrane actuators. As a result, the switch matrix achieves effective isolation between RF lines, enabling non-blocking, dynamic routing of signals across any available input and output ports. Through-substrate interconnects help reduce RF and DC interference, providing a scalable solution to address challenges in insertion loss consistency and isolation performance in RF switch matrices.

### RELATED APPLICATIONS

The subject patent application is related to U.S. patent application Ser. No. ______, filed ______, and entitled “BROADBAND RADIO FREQUENCY MICRO-ACTUATOR SWITCH WITH HIGH ISOLATION” (docket no. 141545.01/DELLP1476US), and U.S. patent application Ser. No. ______, filed ______, and entitled “SCALABLE RADIO FREQUENCY SWITCH MATRIX FOR MULTIPORT SIGNAL ROUTING” (docket no. 141548.01/DELLP1479US), the entireties of which patent applications are hereby incorporated by reference herein.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example layout of a switch matrix highlighting various components therein, in accordance with various example embodiments and implementations of the subject disclosure.

FIGS. 2A and 2B are side views of an example micromembrane actuator showing the general operating principle (open, FIG. 2A, and closed, FIG. 2B) via a cantilever-based connector, in accordance with various example embodiments and implementations of the subject disclosure.

FIGS. 3A and 3B show a general semitransparent layout and top view, respectively, of an example dual-cantilever micromembrane actuator device, in accordance with various example embodiments and implementations of the subject disclosure.

FIG. 4 is an isometric top view representation of an example dual-cantilever micromembrane actuator device, in accordance with various example embodiments and implementations of the subject disclosure.

FIG. 5 is an isometric bottom view representation of one example dual-cantilever micromembrane actuator device, showing control contact pads with voltages applied by a controller, in accordance with various example embodiments and implementations of the subject disclosure.

FIG. 6 is a top view representation of an example layout of a switch matrix using micromembrane actuator devices, including example dual cantilever micromembrane actuator devices, in accordance with various example embodiments and implementations of the subject disclosure.

FIG. 7 is a top view representation of the example switch matrix of FIG. 6, in accordance with various example embodiments and implementations of the subject disclosure.

FIG. 8 is a bottom view representation of the example switch matrix of FIG. 6, in accordance with various example embodiments and implementations of the subject disclosure.

FIG. 9 is a three-dimensional (3D) top and side view of an example switch matrix using micromembrane actuator devices, in accordance with various example embodiments and implementations of the subject disclosure.

FIG. 10 is a 3D bottom and side view of the example switch matrix of FIG. 8 using micromembrane actuator devices, in accordance with various example embodiments and implementations of the subject disclosure.

FIG. 11A is a cross-sectional view of an example switch matrix using dual micromembrane actuator devices, in accordance with various example embodiments and implementations of the subject disclosure.

FIG. 11B is a 3D zoomed-in view of a crossover potion of the example switch matrix of FIG. 8, in accordance with various example embodiments and implementations of the subject disclosure.

FIG. 12 is a top view representation of the example layout of a switch matrix of FIG. 11 in a configuration in which two radio frequency (RF) signal paths are available by control of the switches, in accordance with various example embodiments and implementations of the subject disclosure.

FIG. 13 is a top view representation of the example layout of a switch matrix of FIG. 11 in an alternative configuration in which two other radio frequency (RF) signal paths (relative to FIG. 12) are available by alternative control of the switches, in accordance with various example embodiments and implementations of the subject disclosure.

FIGS. 14A, 14B and 15A are graphical representations of return loss, insertion loss and isolation simulation results, respectively, for the two RF signal paths corresponding to FIG. 12, in accordance with various embodiments and implementations of the subject disclosure.

FIGS. 15B, 16A and 16B are graphical representations of return loss, insertion loss and isolation simulation results, respectively, for a first of the two RF signal paths corresponding to FIG. 13, in accordance with various embodiments and implementations of the subject disclosure.

FIGS. 17A, 17B and 18 are graphical representations of return loss, insertion loss and isolation simulation results, respectively, for a second of the two RF signal paths corresponding to FIG. 13, in accordance with various embodiments and implementations of the subject disclosure.

FIG. 19 is a flow diagram showing example operations related to electrically coupling one or more selectable RF ports to another RF port based on controlling states of mechanical micro-actuator-based switches, in accordance with various aspects and implementations of the subject disclosure.

### DETAILED DESCRIPTION

Various implementations and embodiments of the technology described herein are generally directed towards a highly efficient, low loss, and compact radio frequency (RF) switch matrix. The switch matrix integrates mechanical micro-actuator-based switch devices, enabling multistate operation for routing an input signal from any available port to any available free port, such as embodied in a four-port switch with distinct states for flexible signal routing across multiple ports.

The technology provides a mechanical micro-actuator-based switch matrix designed for high isolation between RF transmission paths. Utilizing a crossover with a tuned permittivity patch and a mix of single and dual-membrane actuators, the mechanical micro-actuator-based switch matrix device achieves effective isolation between RF lines, enabling non-blocking, dynamic routing of signals across any available input and output ports. One implementation of the device includes six switches, four of which use single-membrane actuators, while two feature dual-membrane actuators. Through-substrate interconnects help to minimize RF and DC interference, providing a scalable solution to address challenges in insertion loss consistency and isolation performance in RF switch matrices.

In general, achieving high isolation between non-connected paths and maintaining consistent insertion loss across states are significant challenges for conventional RF switch matrices. For example, standard single-pole multiple-throw (SPMT) switches offer only a single common input with multiple selectable outputs, limiting flexibility and dynamic signal routing. Additionally, crossover interference in dense RF circuitry complicates matrix design and degrades performance. Efforts to reduce crossover interference in dense RF layouts have included RF matching techniques and additional isolation layers. Nonetheless, these solutions struggle to balance the need for high isolation with consistent insertion loss across multiple states, often at the cost of increased design complexity. In contrast, the switch matrix technology described herein facilitates a scalable solution that can dynamically route RF signals between multiple ports while maintaining high isolation and consistent insertion loss.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

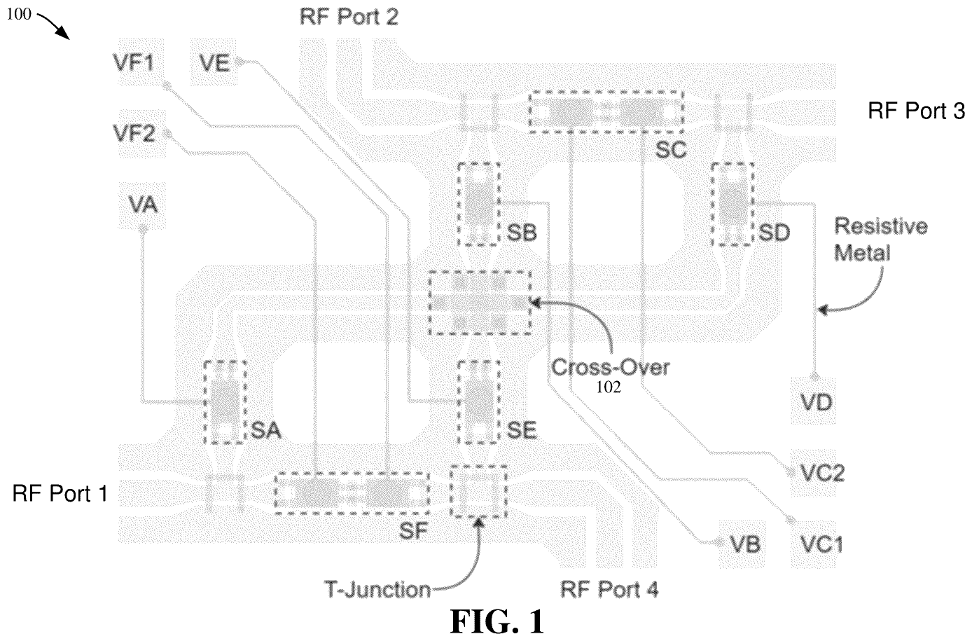

FIG. 1 shows an example 2×2 mechanical micro-actuator-based RF switch matrix (device) 100 that allows non-blocking signal routing between any two available RF ports, RF Port 1-RF Port 4. The example device includes six switches (SA, SB, SC, SD, SE, SF); four of the switches (SA, SB, SD, SE) are single-membrane actuators and two of the switches (SC, SF) are dual-membrane actuators as described herein. A crossover 102 designed with a tuned permittivity patch provides isolation between intersecting RF lines, allowing simultaneous signal transmission without interference.

The switches are actuated or de-actuated based on whether an actuation voltage is present at contact pads VA, VB, VD, VE for the single-membrane actuators SA, SB, SD, SE, respectively, and VC1, VC2, VF1 and VF2 for the dual-membrane actuators SC and SF (two contact pads each). Note that there can be some resistance (resistive metal) between the contact pads and the switches (their electrostatic electrode or electrodes as described herein) so that the electrostatic energy is appropriate for actuation. T-junctions couple each of the RF ports to corresponding subsets of the switches.

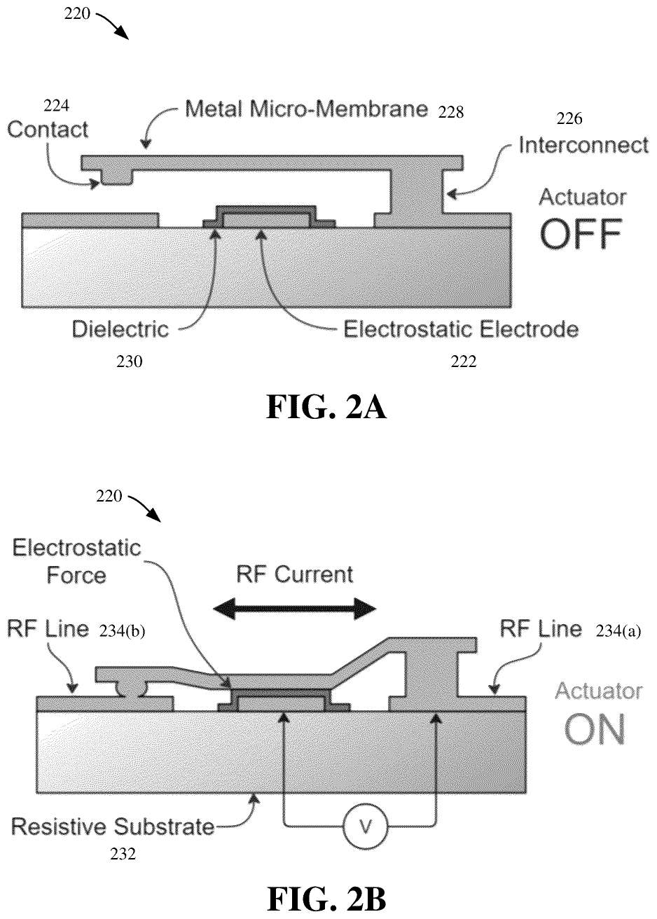

Turning to micromembrane switches in general, FIG. 2A shows an example cantilever type micromembrane actuator 220 in an actuator OFF State, and FIG. 2B shows the example cantilever type micromembrane actuator 220 in an actuator ON state. When no voltage (or too low of a voltage to actuate) is applied to the electrostatic electrode 222 as in FIG. 2A, the micromembrane's contact 224 remains in a lifted state due to the structural configuration of the metal micromembrane 228. In this OFF state, RF current (e.g., obtained an interconnect 226) cannot flow across the RF line, effectively isolating the circuit.

FIG. 2B shows electrostatic actuation, in which applying a voltage V difference to the electrode (relative to ground) creates an electrostatic force that pulls the micromembrane 228 down towards the resistive substrate 232. This electrostatic force overcomes the membrane's structural tension, bringing its contact(s) 224 into contact with the RF line 234(b) at its non-anchored end. In this actuator ON state, the electrical coupling between the micromembrane and RF line is established, allowing RF current to pass through. The RF signal can then flow across the circuit, enabling connectivity between the RF lines 234(a) and 234(b). Note that FIG. 2A shows a dielectric 230 that electrically insulates the electrostatic electrode 222 from the RF lines 234(a) and 234(b).

In one example implementation, a micro-actuator-based switch solution described herein includes a micro-actuator-based switch that enhances isolation by connecting two micro-cantilevers back-to-back. This back-to-back configuration significantly increases isolation performance by increasing the overall vertical distance between RF lines and contact points, which generally gets less due to residual stresses after releasing the cantilever beams. This micro-actuator-based switch configuration also lowers the actuation voltage and a lower gap is needed to generate sufficient pull-in force between membrane and electrode, making it well-suited for applications demanding high signal integrity. Through-substrate interconnects provide DC power for the electrostatic actuation, allowing precise control over switch states. The design also offers a compact form factor, ideal for integration in RF systems where space and performance are significant considerations.

In general, micromembrane actuators enable relatively highly precise, relatively low loss switching in RF systems, offering a reliable alternative to traditional semiconductor and mechanical switches. Their ability to toggle at high-speed with minimal loss, linearity, and high-power handling makes them suitable for reconfigurable antennas, tunable filters, and multi-band communication systems. Note that other, common types of switch configurations include electrostatic, piezoelectric, and thermal actuation switches; each type has certain advantages in terms of speed, power consumption, and mechanical stability. Electrostatic actuators are used due to their low power consumption and rapid actuation.

Further note that while micromembrane actuators were evaluated in the past decade due to their ON-state performance, with micro-scale cantilevers having curvature after manufacturing, in prior micromembrane actuators the isolation performance suffers. Indeed, conventional switch designs, such as microelectromechanical systems (MEMS) switches, face limitations in isolation performance, especially when subjected to high-frequency applications. Moreover, standard MEMS based cantilever solutions also suffer from residual stresses from manufacturing, leading to poor isolation performance. Such designs typically have performance pitfalls from leakage and insufficient isolation, reducing overall system effectiveness. While stacked designs can improve isolation, they often increase complexity and size, which are complex to manufacture and have poor reliability issues.

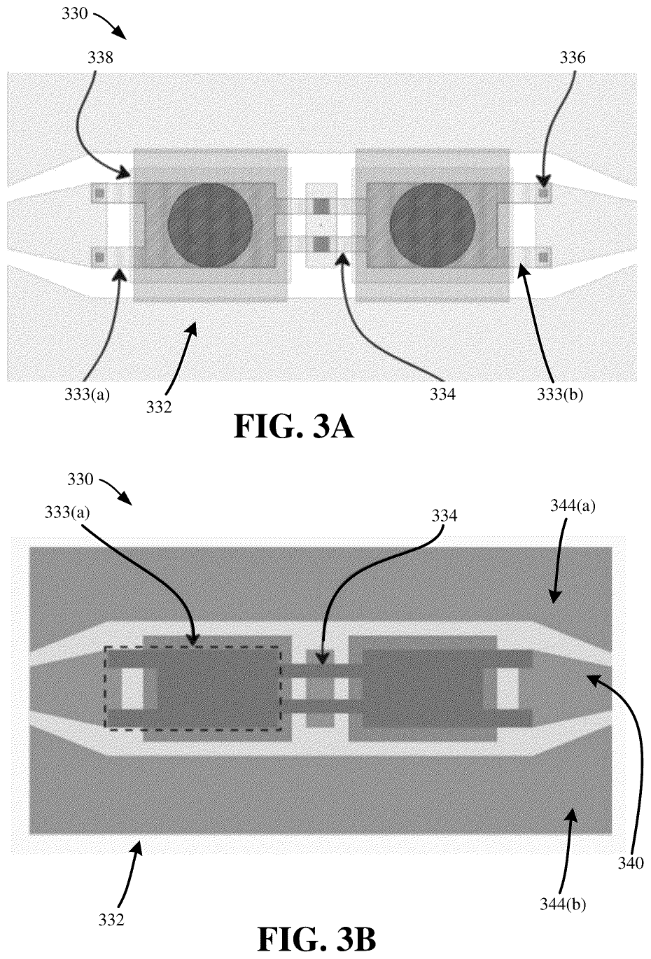

FIGS. 3A and 3B show an example layout and top view, respectively, of a dual micro-actuator-based switch device fabricated on a substrate 332. As can be seen, in this example implementation, two micromembranes 333(a) and 333(b) are connected back to and anchored (back-to-back connected anchors 334) on an isolated metal island (one of which is labeled 336, RF disconnected).

In this example implementation, dual metal contacts (one of which is labeled 338) are at the forked ends of the cantilever micromembranes. The RF signal line input-to-output (or vice-versa) port 340 (shown between two RF ground regions 344(a) and 3440(b)) is connected by actuating both the actuators in conjunction with one another; note that individual voltage contact pads are designed to compensate for different manufacturing tolerances of residual stress by allowing different, individual voltages to be applied to deform each micromembrane as needed for a given micromembrane displacement. The amount of electrostatic pull-in force is generated by each DC voltage to switch the device to its ON state; removal of the voltage, which can include sufficiently lowering the voltage to zero or near-zero volts, switches the device to its OFF state. Although it is feasible to de-actuate only one micromembrane to disconnect the RF line, improved isolation is achieved by de-actuating both micromembranes together relative to de-actuating only one. As will be understood, such an example design results in a dual broadband in-line micro-actuator-based switch with excellent RF performance over DC to (at least) 40 GHz. Note that a shared anchor (e.g., including a shared dual-anchor configuration) can be positioned between the dual micromembrane portions. Dielectric materials can be included beneath the micromembrane portions to help with RF signal isolation.

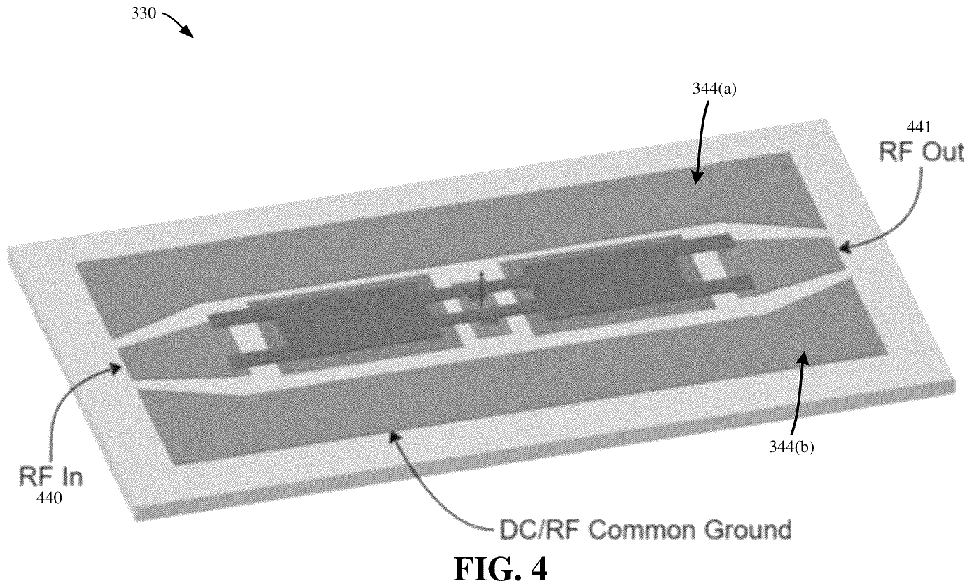

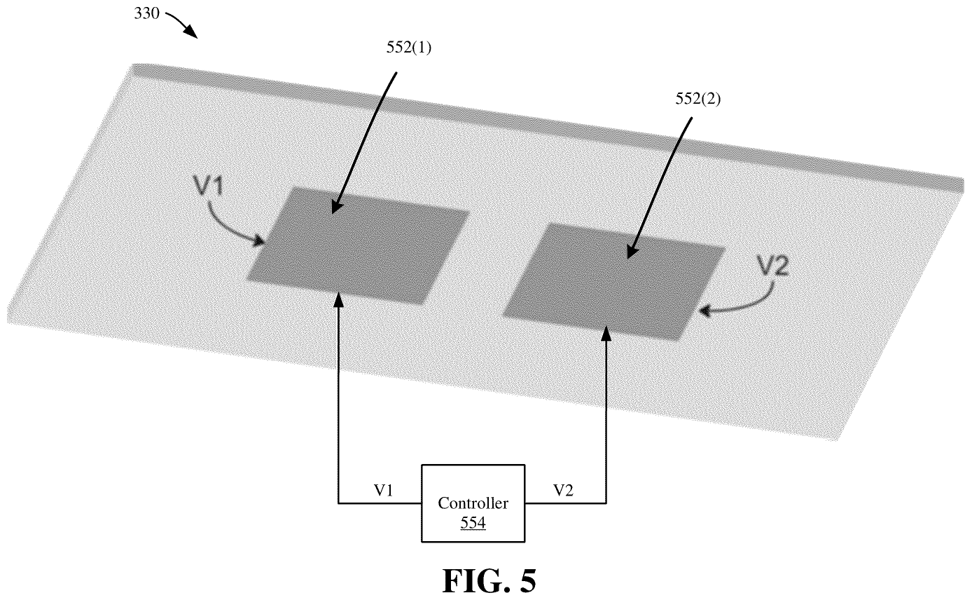

FIGS. 4 and 5 are top and bottom isometric views of the micro-actuator-based switch device 330 depicting an RF-input port 440 and RF output port 441 shown between the two RF ground regions 344(a) and 344(b)). Note that the DC voltage bias can share the RF common ground, with the positive voltages V1 and V2 applied to the two voltage contact pads 552(1) and 552(2) coupled to the electrostatic electrodes, as shown in FIG. 5.

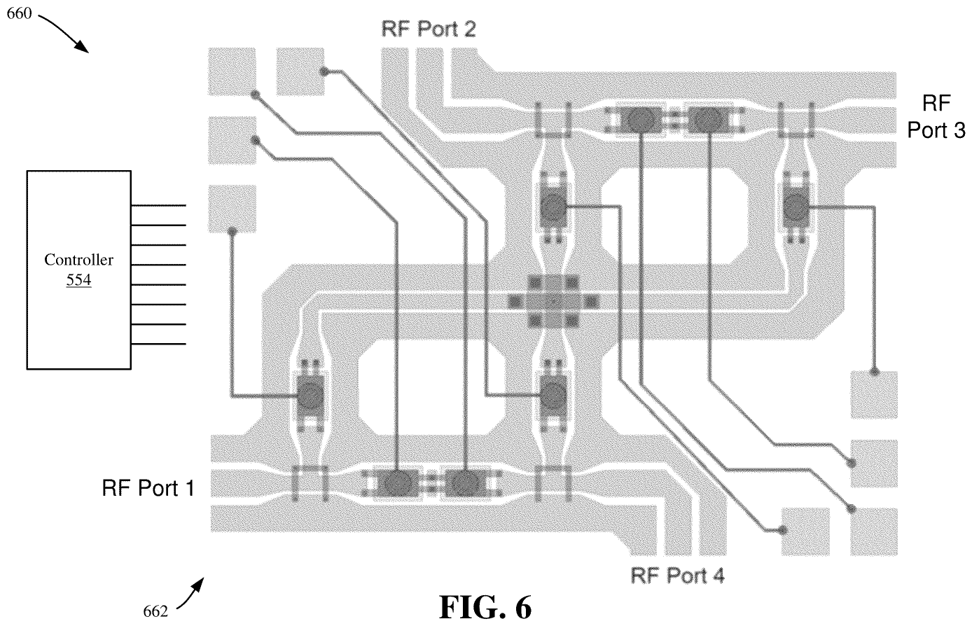

As shown in FIGS. 5 and 6, a system 660 (FIG. 6) can include a controller 554 that can controllably apply the voltages (e.g., including V1 and V2 for a dual micro-actuator-based switch as in FIG. 5) to the contact pads 552(1) and 552(2) of the switch device 662, and controllably remove the voltages (e.g., V1 and V2 in FIG. 5) to de-actuate the micromembranes. The two voltages applied to the two contact pads 552(1) and 552(2) of a dual micro-actuator-based switch may differ to individually actuate the two micromembranes as appropriate, to compensate as appropriate for possibly different tolerances following manufacturing that correspond to different actuation voltages.

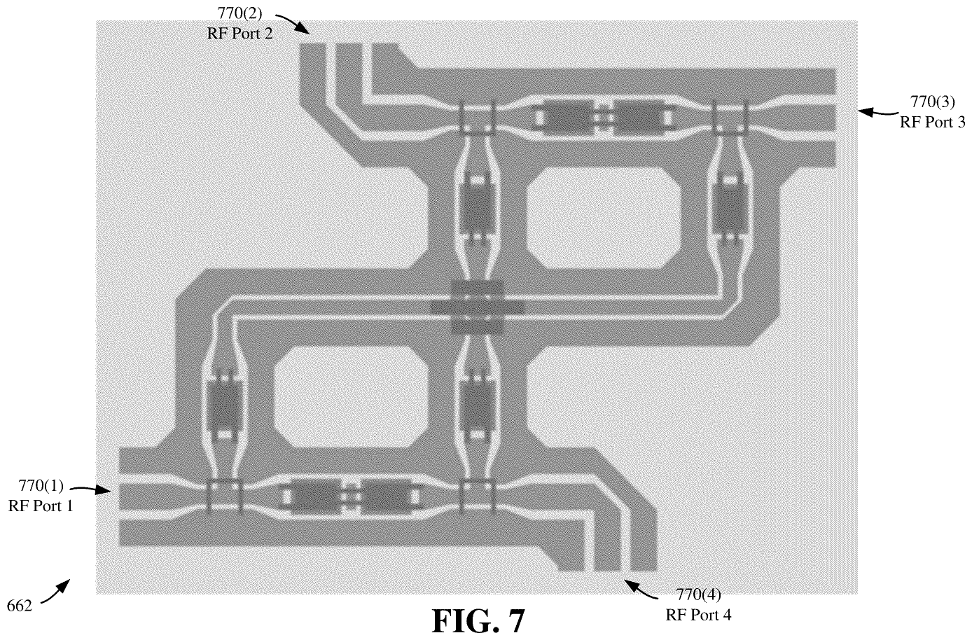

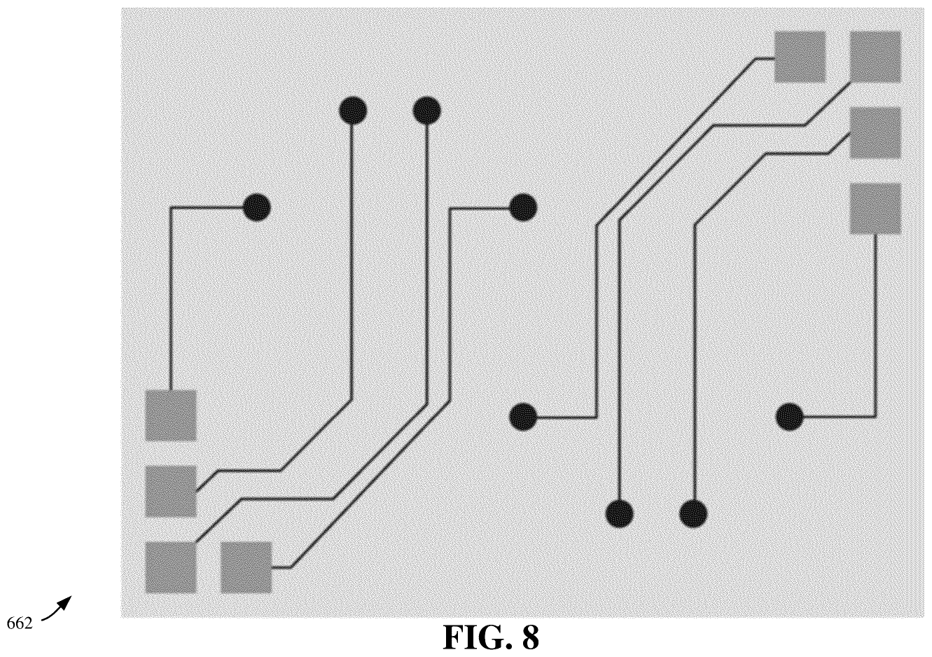

FIG. 7 is a top view of the 4×4 switch device 662 showing the four RF ports 770(1)-770(4) corresponding to RF Port 1-RF Port 4, respectively. The switches, crossover and T-junctions are visible in FIG. 7, showing a substantially symmetrical configuration. Note that two switches (whether a dual micro-actuator-based switch or two single micro-actuator-based switches) are in each signal path between ports. Note that instead of a dual actuator device, it is feasible to have two single switches coupled together (a total of eight switches), however there can be fabrication advantages (e.g., a single central anchor point for the cantilevers) to having a dual actuation device. FIG. 8 is a bottom view of the switch device 662 showing the eight actuation pads each coupled to an interconnect to actuate one of the eight electrodes of the six switches.

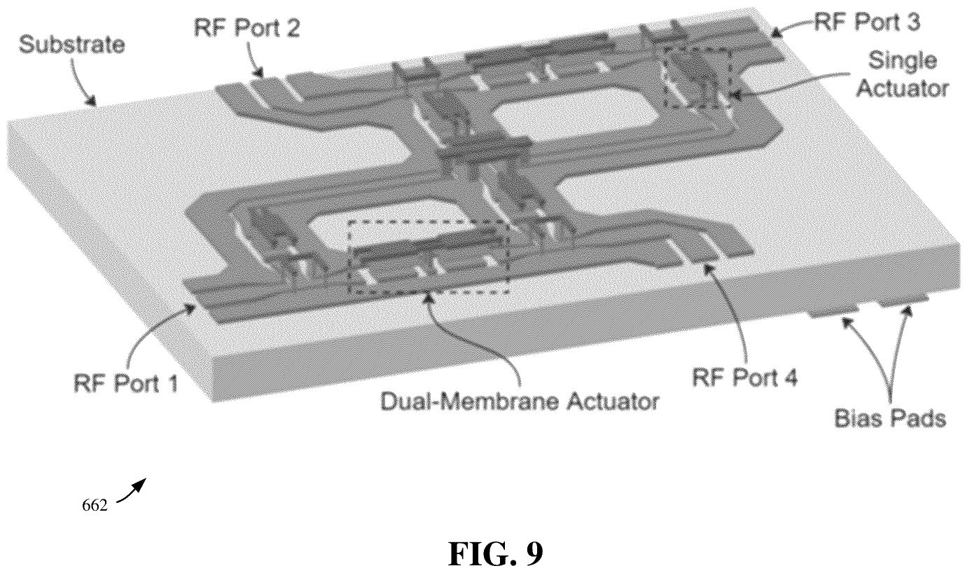

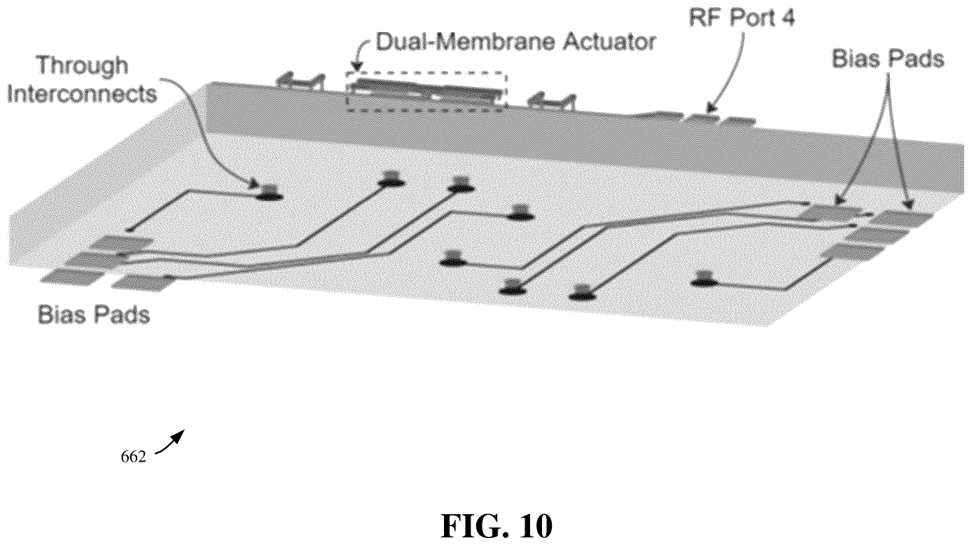

FIG. 9 is a three-dimensional (3D) top and side view of the switch matrix device 662 fabricated on a substrate, with one single actuator and one dual-actuator identified, along with the four RF ports (RF Port 1-RF Port 4) and two of the bias pads. FIG. 10 is a bottom and side 3D view of the switch matrix device 662 showing the eight bias pads and corresponding through interconnects to the switches' electrodes. The use of through-substrate interconnects further helps reduce RF and DC interference.

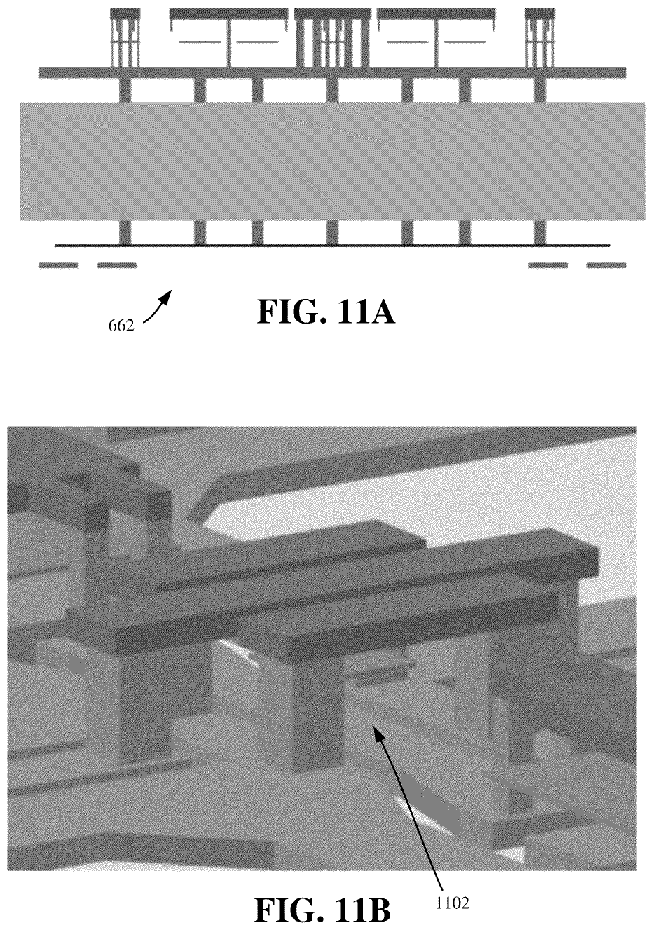

FIG. 11A is a two-dimensional cross-sectional view of the switch matrix device 662, in which the some of the bias pads and interconnects to the surface switch components are visible. FIG. 11B is an enlarged view of the crossover portion of 1102 of the switch matrix device 662.

Turning to RF connections, the switch matrix device 662 is designed to allow two simultaneous connections for non-blocking signal routing; (note however that it is feasible to use the device for coupling one port to more than one other port, e.g., RF port 1 can be coupled to RF Port 2, RF Port 3, and/or RF port 4). In general, the switch matrix allows for dynamic routing of RF signals between any two available RF ports; note that the switch matrix device operates differently from a standard single-pole multiple-throw switch that only has one common RF input and multiple outputs, with only one output able to be selected at a time.

For non-blocking signal routing, the device is designed with two switch contacts per path to keep the variation in insertion loss substantially equal between states. Note that while a 2×2 matrix is described herein, the design is scalable to multiple port matrices, e.g., by coupling multiple such devices together.

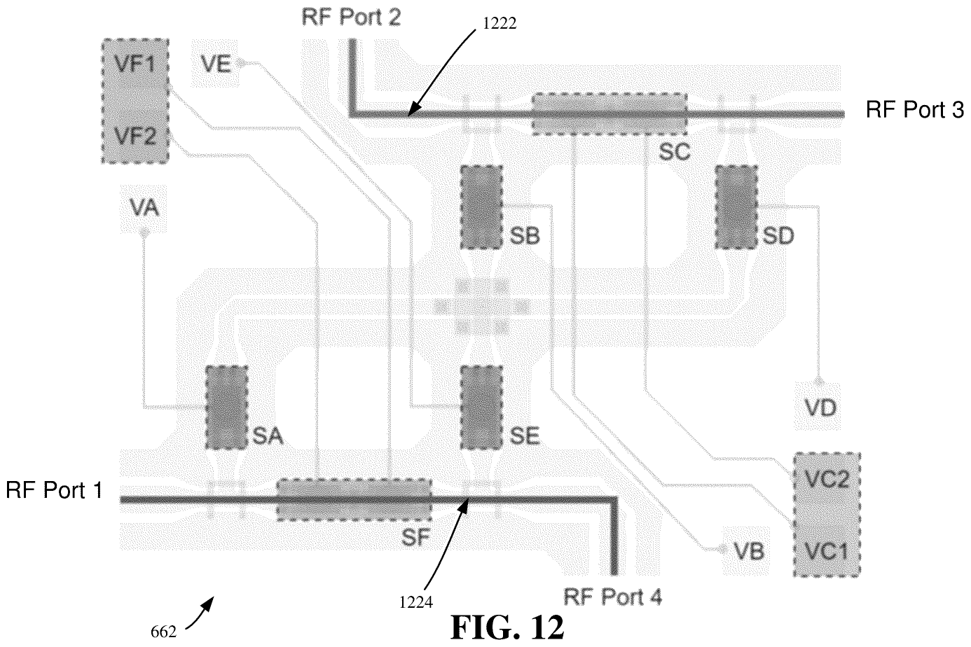

FIG. 12 shows two of the possible RF signal paths, which can be connected individually or simultaneously. By actuating dual switch SC via bias applied at VC1 and VC2, the RF Port 2 is coupled to RF Port 3 as indicated by the upper dark line 1222. This can be a single connection for a given RF signal, or can be simultaneous with a connection between RF port 1 and RF port 2, as indicated by the lower dark line 1224, which is accomplished by actuating dual switch SF (bias applied at VF1 and VF2). The other switches are in their de-actuated states in this non-blocking configuration example.

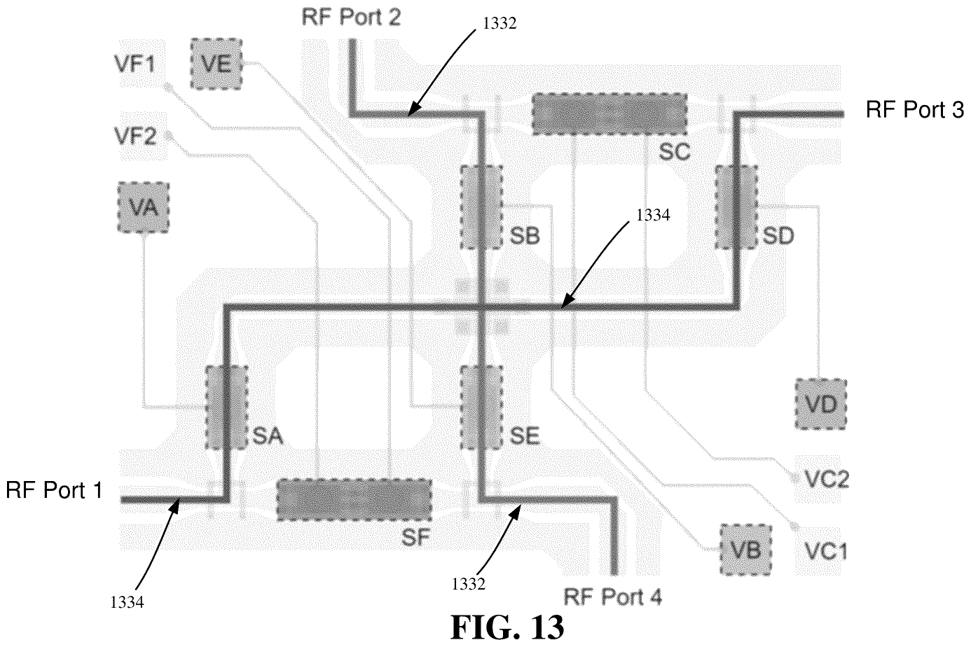

FIG. 13 shows another two of the possible RF signal paths, which as in FIG. 12 can be connected simultaneously. By actuating single switches SB and SE (bias applied at VB and VE, respectively), RF Port 2 is coupled to RF Port 4 as indicated by the dark line 1332. This can be a single connection for a given RF signal, or can be simultaneous with a connection between RF port 1 and RF port 4, as indicated by the lower dark line 1334, which is accomplished by actuating single switches SA and SD (bias applied at VA and VD, respectively). Note that in the configuration of FIG. 13, the crossover allows the routing of two independent RF signals without interference by proper RF matching and by including a tuned permittivity patch between two metal layers. The other switches are in their de-actuated states in this non-blocking configuration example. The switch matrix thus facilitates significant utilization of any available RF signal paths in radios, test equipment, or wireless networks.

The following table, TABLE 1, summarizes the bias mapping for the various modes of operation in FIGS. 12 and 13 (with 5V being the actuation voltage):

TABLE 1

| Mode of | Voltage Map | | | | | | | |
|---|---|---|---|---|---|---|---|---|
| Operation | VA | VB | VC1 | VC2 | VD | VE | VF1 | VF2 |
| Path 1 (P1-P4) | 0 | 1 | 0 | 0 | 0 | 0 | 5 V | 5 V |
| Path 2 (P2-P3) | 0 | 0 | 5 V | 5 V | 0 | 0 | 0 | 0 |
| Path 3 (P1-P3) | 5 V | 0 | 0 | 0 | 5 V | 0 | 0 | 0 |
| Path 4 (P2-P4) | 0 | 5 V | 0 | 0 | 0 | 5 V | 0 | 0 |

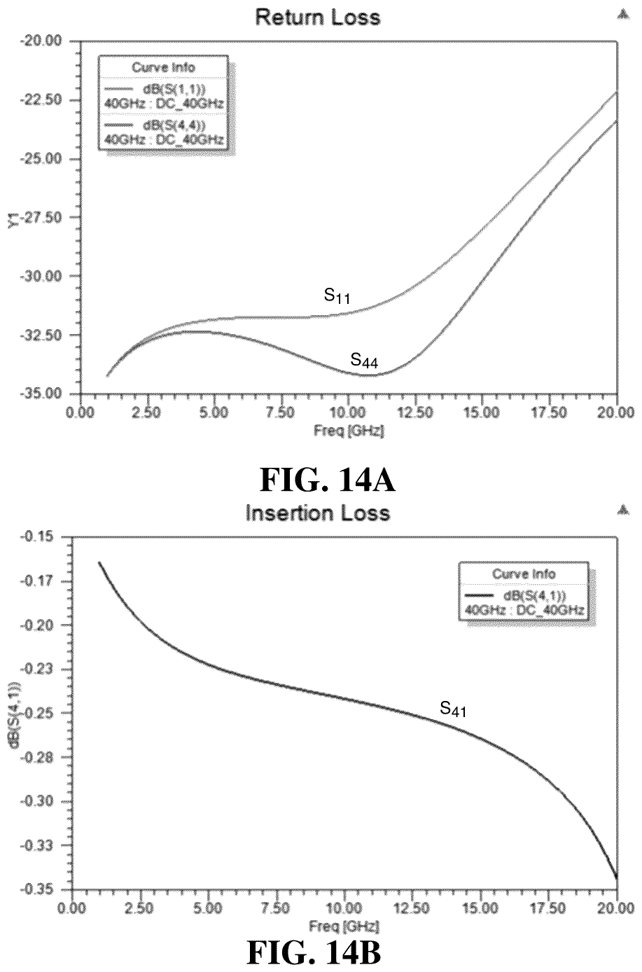

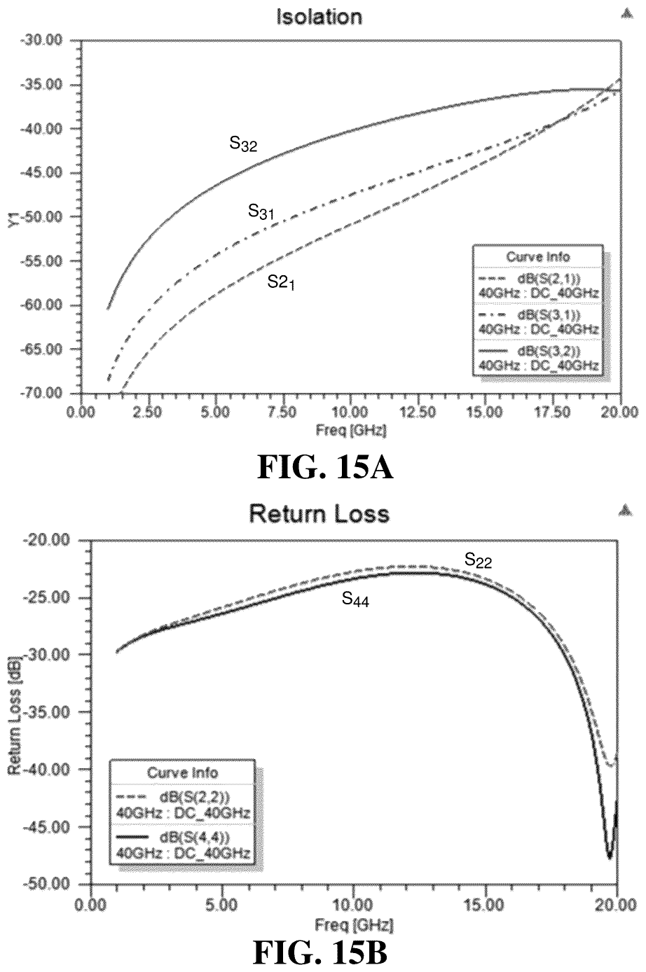

FIGS. 14A, 14B and 15A show the simulated performance results of the device for either of signal paths 1 and 2. In FIG. 14A, it is seen that the return loss is more than −20 dB from DC to 20 GHz. The insertion loss (FIG. 14B) is lower than −0.35 dB from DC to 20 GHz. The performance is identical or substantially identical for signal path 1 and signal path 2 because of the symmetry of the switch device. In FIG. 15A, it is seen that isolation is higher than −35 dB over the band due to the use of the dual-membrane actuators in the signal paths.

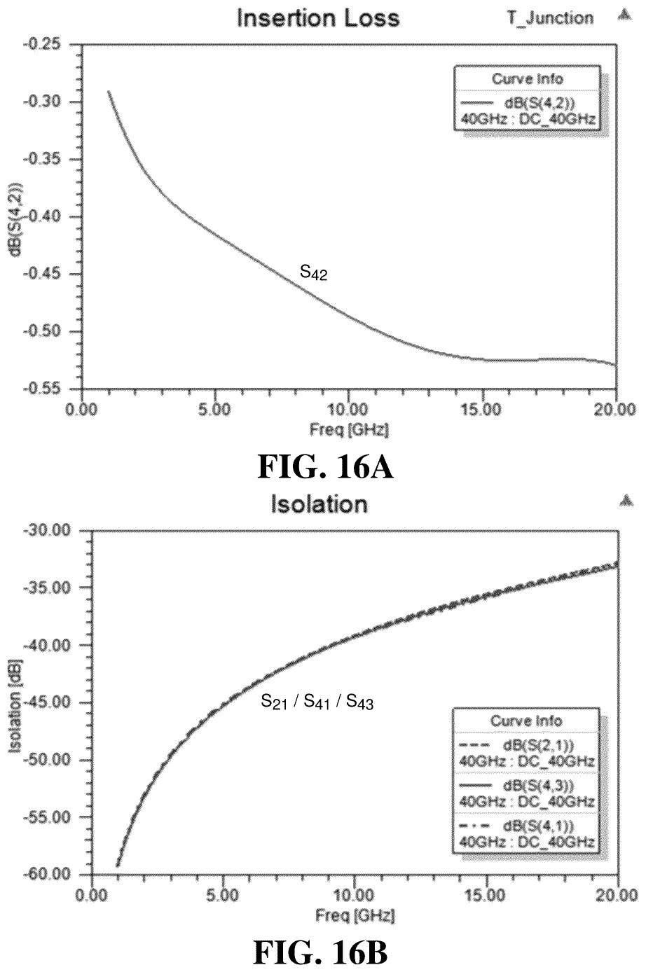

FIGS. 15B, 16A and 16B show the simulated performance results of the device for signal path 3. In FIG. 15B, it is seen that the return loss is more than −22 dB from DC to 20 GHz. The insertion loss (FIG. 16A) is lower than −0.52 dB from DC to 20 GHz. In FIG. 16B, it is seen that isolation is higher than −32 dB over the band due to the use of two single membrane actuators in the path and the dual-actuators keeping the unwanted signals isolated while in their de-actuated states.

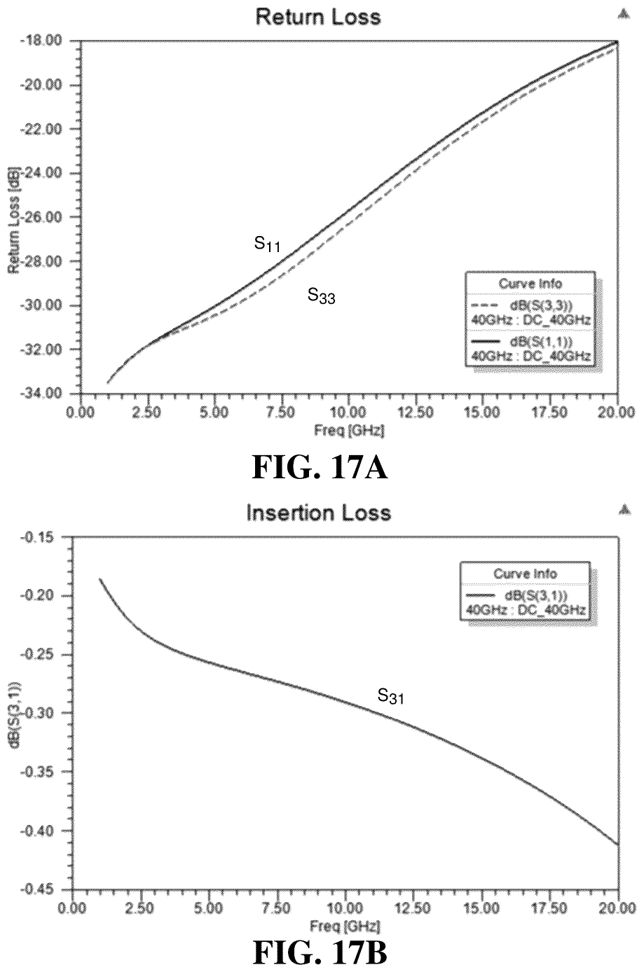

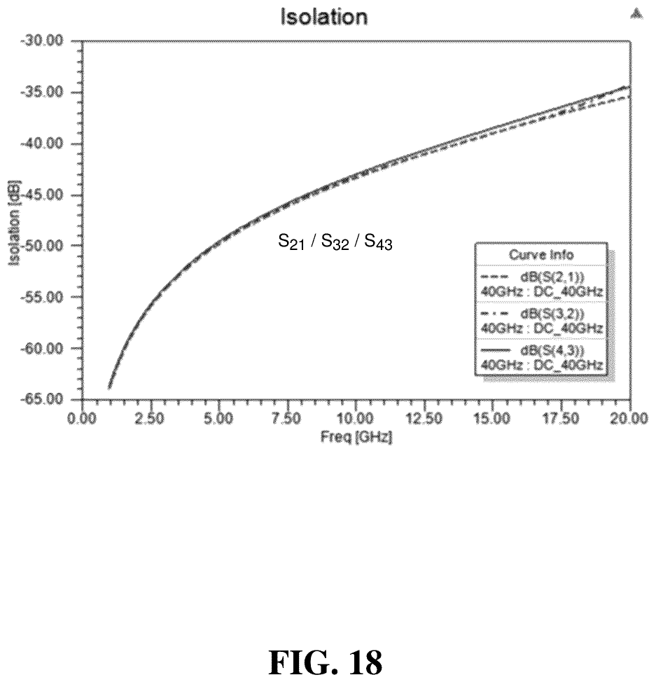

FIGS. 17A, 17B and 18 show the simulated performance results of the device for signal path 4. In FIG. 17A, it is seen that the return loss is more than −18 dB from DC to 20 GHz. The insertion loss (FIG. 17B) is lower than −0.42 dB from DC to 20 GHz. In FIG. 18, it is seen that isolation is higher than −35 dB over the band due to the use of two single membrane actuators in the path and the dual-actuators keeping the unwanted signals isolated while in their de-actuated states.

One or more implementations can be embodied in a device, including a radio frequency (RF) switch matrix. The RF switch matrix can include RF ports, and a group of mechanical micro-actuator-based switches coupled to the RF ports. Application of first respective voltages selectively controlled by a controller can determine an operational state of the RF switch matrix, corresponding to a first subgroup of respective mechanical micro-actuator-based switches controlled to be in actuated states, and a second subgroup of respective mechanical micro-actuator-based switches controlled to be in de-actuated states. The operational state electrically couples a first RF port of the RF ports to a fourth RF port of the RF ports.

The first subgroup of the respective mechanical micro-actuator-based switches can include at least two respective mechanical micro-actuator-based switches controlled to be in the actuated states.

The two respective mechanical micro-actuator-based switches can include a dual-membrane-cantilever switch device.

The respective actuated states of the first subgroup and the respective de-actuated states of the second subgroup can further electrically couple a second RF port of the RF ports to a third RF port of the RF ports.

The first subgroup of the respective mechanical micro-actuator-based switches can include a first subset of least two respective mechanical micro-actuator-based switches controlled to be in the actuated states to couple the first RF port to the fourth RF port, and a second subset of least two other respective mechanical micro-actuator-based switches controlled to be in the actuated states to couple the second RF port to the third RF port, and in which a number of switches in the first subset equals a number of switches in the second subset.

The operational state can be a first operational state, the actuated states can be first actuated states, the de-actuated states can be first de-actuated states, and the switches of the RF switch matrix can be controlled to selectively change the first operational state to a second operational state that can include a third subgroup of the respective mechanical micro-actuator-based switches controlled to be in second actuated states, and a fourth subgroup of the respective mechanical micro-actuator-based switches controlled to be in a second de-actuated states; the second operational state electrically couples the first RF port of the RF ports to a third RF port of the RF ports.

The third subgroup of the respective mechanical micro-actuator-based switches can include two respective mechanical micro-actuator-based switches controlled to be in the second actuated states.

The second operational state can electrically decouple the first RF port from the fourth RF port.

The second operational state can electrically couple a second RF port of the RF ports to the fourth RF port.

The device can include a crossover point that facilitates the electrically coupling of the first RF port to a third RF port of the RF ports, and facilitates the electrically coupling of a second RF port of the RF ports to the fourth RF port.

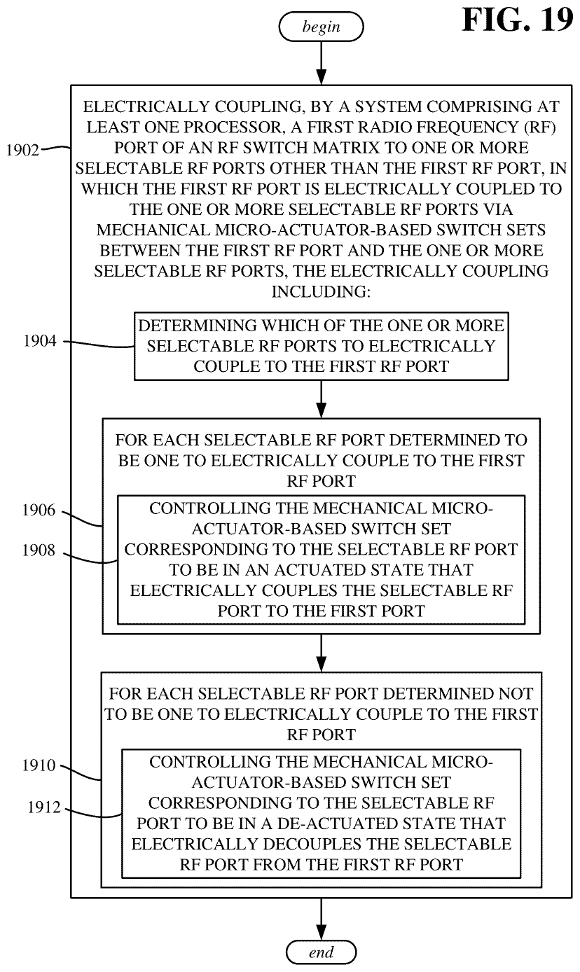

One or more example embodiments, implementations, and/or operations, such as corresponding to example operations of a method, can be represented in FIG. 19. Example operation 1902 represents electrically coupling, by a system comprising at least one processor, a first radio frequency (RF) port of an RF switch matrix to one or more selectable RF ports other than the first RF port, in which the first RF port can be electrically coupled to the one or more selectable RF ports via mechanical micro-actuator-based switch sets between the first RF port and the one or more selectable RF ports. The electrically coupling includes example operations 1904-1912. Example operation 1904 represents determining which of the one or more selectable RF ports to electrically couple to the first RF port. Example operation 1906 represents, for each selectable RF port determined to be one to electrically couple to the first RF port, controlling the mechanical micro-actuator-based switch set corresponding to the selectable RF port to be in an actuated state that electrically couples the selectable RF port to the first port (example operation 1908). Example operation 1910 represents, for each selectable RF port determined not to be one to electrically couple to the first RF port, controlling the mechanical micro-actuator-based switch set corresponding to the selectable RF port to be in a de-actuated state that electrically decouples the selectable RF port from the first RF port (example operation 1912).

Controlling the mechanical micro-actuator-based switch set corresponding to the selectable RF port to change the mechanical micro-actuator-based switch set to the actuated state can include applying at least one voltage to at least one contact pad coupled to the mechanical micro-actuator-based switch set to set the mechanical micro-actuator-based switch set switch set to the actuated state.

At least one of the mechanical micro-actuator-based switch sets can include a dual-switch device, and applying the at least one voltage to the at least one contact pad can include applying a first voltage to a first contact pad coupled to a first switch of the dual-switch device, and applying a second voltage to a second contact pad coupled to a second switch of the dual-switch device.

The first RF port can be an input port that obtains an input signal, and the electrically coupling can include determining at least one of the one or more selectable RF ports as at least one corresponding output port usable to obtain the input signal.

The first RF port can be an output port, and further operations can include determining, by the system, a single selectable RF port of the one or more selectable RF ports to be an input port that obtains an input signal; the electrically coupling can couple the single selectable RF port to the first RF port.

The electrically coupling can be a first electrical coupling operation that couples the first RF port to a fourth RF port of the one or more selectable RF ports via a first mechanical micro-actuator-based switch set being controlled to be in a first actuated state, decouples the first RF port from a third RF port of the one or more selectable RF ports via a second mechanical micro-actuator-based switch set controlled to be in a first de-actuated state, and decouples the first RF port from a second RF port of the one or more selectable RF ports via a third mechanical micro-actuator-based switch set controlled to be in a second de-actuated state. Further operations can include in a second electrically coupling operation, electrically coupling, by the system, the second RF port to the third RF port via controlling a fourth mechanical micro-actuator-based switch set to be in a second actuated state that electrically couples the second RF port to the third RF port.

One or more implementations can be embodied in a switch matrix. The switch matrix can include a group of RF ports comprising a first port, a second port, a third port, and a fourth port, and respective mechanical micro-actuator-based switch sets comprising a respective first switch, a respective second switch, a respective third switch, a respective fourth switch, a respective fifth switch, and a respective sixth switch. The respective mechanical micro-actuator-based switch sets can be controlled by respective applied voltage sets to at least one of: set the respective sixth switch to a respective sixth actuated state to electrically couple the first RF port to the fourth RF port to obtain a first signal path, set the respective third switch to a respective third actuated state to electrically couple the second RF port to the third RF port to obtain a second signal path, set the respective first switch to a respective first actuated state and set the respective fourth switch to a respective fourth actuated state to electrically couple the first RF port to the third RF port to obtain a third signal path, or set the respective second switch to a respective second actuated state and set the respective fifth switch to a respective fifth actuated state to electrically couple the second RF port to the fourth RF port to obtain a fourth signal path.

The respective third switch can include a first dual-membrane-cantilever switch device controlled by a respective third applied voltage set that can include a first voltage and a second voltage, and the respective sixth switch can include a second dual-membrane-cantilever switch device controlled by a respective sixth applied voltage set that can include a third voltage and a fourth voltage.

Each of the first signal path, the second signal path, the third signal path and the fourth signal path can include two of the respective mechanical micro-actuator-based switches; the first signal path does not share a switch with the second signal path, the third signal path or the fourth signal path, the second signal path does not share a switch with the third signal path or the fourth signal path, and the third signal path does not share a switch with the fourth signal path.

The first switch port can be electrically coupled to the fourth switch port, and the first switch and the fourth switch port can be de-actuated to electrically decouple the first switch from the third switch port.

As can be seen, the technology described herein facilitates an RF switch matrix. In one implementation, a dual-membrane design in some of the switches enhances isolation performance, reducing leakage between non-connected paths and improving overall signal integrity. The design reduces RF interference by implementing a tuned permittivity patch at crossovers, whereby the switch matrix minimizes interference between crossing RF lines, achieving high isolation without additional circuitry. This helps to minimize insertion loss variation across multiple states. Namely, with the same number (e.g., two) of switch contacts per path, the switch matrix maintains consistent insertion loss across different states, a significant feature for high-performance RF applications in that the insertion loss delta does not change with changing the RF signal paths.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) switch matrix, comprising:
RF ports; and
a group of mechanical micro-actuator-based switches coupled to the RF ports, wherein application of first respective voltages selectively controlled by a controller determines an operational state of the RF switch matrix, corresponding to a first subgroup of respective mechanical micro-actuator-based switches controlled to be in actuated states, and a second subgroup of respective mechanical micro-actuator-based switches controlled to be in de-actuated states, and
wherein the operational state electrically couples a first RF port of the RF ports to a fourth RF port of the RF ports.

2. The device of claim 1, wherein the first subgroup of the respective mechanical micro-actuator-based switches comprises at least two respective mechanical micro-actuator-based switches controlled to be in the actuated states.

3. The device of claim 2, wherein the two respective mechanical micro-actuator-based switches comprise a dual-membrane-cantilever switch device.

4. The device of claim 1, wherein the respective actuated states of the first subgroup and the respective de-actuated states of the second subgroup further electrically couple a second RF port of the RF ports to a third RF port of the RF ports.

5. The device of claim 4, wherein the first subgroup of the respective mechanical micro-actuator-based switches comprises a first subset of least two respective mechanical micro-actuator-based switches controlled to be in the actuated states to couple the first RF port to the fourth RF port, and a second subset of least two other respective mechanical micro-actuator-based switches controlled to be in the actuated states to couple the second RF port to the third RF port, and wherein a number of switches in the first subset equals a number of switches in the second subset.

6. The device of claim 1, wherein the operational state is a first operational state, wherein the actuated states are first actuated states, wherein the de-actuated states are first de-actuated states, and wherein the switches of the RF switch matrix are controlled to selectively change the first operational state to a second operational state comprising a third subgroup of the respective mechanical micro-actuator-based switches controlled to be in second actuated states, and a fourth subgroup of the respective mechanical micro-actuator-based switches controlled to be in a second de-actuated states, and wherein the second operational state electrically couples the first RF port of the RF ports to a third RF port of the RF ports.

7. The device of claim 6, wherein the third subgroup of the respective mechanical micro-actuator-based switches comprises two respective mechanical micro-actuator-based switches controlled to be in the second actuated states.

8. The device of claim 6, wherein the second operational state electrically decouples the first RF port from the fourth RF port.

9. The device of claim 8, wherein the second operational state electrically couples a second RF port of the RF ports to the fourth RF port.

10. The device of claim 9, further comprising a crossover point that facilitates the electrically coupling of the first RF port to a third RF port of the RF ports, and facilitates the electrically coupling of a second RF port of the RF ports to the fourth RF port.

11. A method, comprising:
electrically coupling, by a system comprising at least one processor, a first radio frequency (RF) port of an RF switch matrix to one or more selectable RF ports other than the first RF port, wherein the first RF port is electrically coupled to the one or more selectable RF ports via mechanical micro-actuator-based switch sets between the first RF port and the one or more selectable RF ports, the electrically coupling comprising:
determining which of the one or more selectable RF ports to electrically couple to the first RF port;
for each selectable RF port determined to be one to electrically couple to the first RF port,
controlling the mechanical micro-actuator-based switch set corresponding to the selectable RF port to be in an actuated state that electrically couples the selectable RF port to the first port; and
for each selectable RF port determined not to be one to electrically couple to the first RF port,
controlling the mechanical micro-actuator-based switch set corresponding to the selectable RF port to be in a de-actuated state that electrically decouples the selectable RF port from the first RF port.

12. The method of claim 11, wherein the controlling of the mechanical micro-actuator-based switch set corresponding to the selectable RF port to change the mechanical micro-actuator-based switch set to the actuated state comprises applying at least one voltage to at least one contact pad coupled to the mechanical micro-actuator-based switch set to set the mechanical micro-actuator-based switch set switch set to the actuated state.

13. The method of claim 12, wherein at least one of the mechanical micro-actuator-based switch sets comprises a dual-switch device, and wherein the applying of the at least one voltage to the at least one contact pad comprises applying a first voltage to a first contact pad coupled to a first switch of the dual-switch device, and applying a second voltage to a second contact pad coupled to a second switch of the dual-switch device.

14. The method of claim 11, wherein the first RF port is an input port that obtains an input signal, and wherein the electrically coupling comprises determining at least one of the one or more selectable RF ports as at least one corresponding output port usable to obtain the input signal.

15. The method of claim 11, wherein the first RF port is an output port, and further comprising determining, by the system, a single selectable RF port of the one or more selectable RF ports to be an input port that obtains an input signal,
wherein the electrically coupling couples the single selectable RF port to the first RF port.

16. The method of claim 12, wherein the electrically coupling is a first electrical coupling operation that:
couples the first RF port to a fourth RF port of the one or more selectable RF ports via a first mechanical micro-actuator-based switch set being controlled to be in a first actuated state,
decouples the first RF port from a third RF port of the one or more selectable RF ports via a second mechanical micro-actuator-based switch set controlled to be in a first de-actuated state, and
decouples the first RF port from a second RF port of the one or more selectable RF ports via a third mechanical micro-actuator-based switch set controlled to be in a second de-actuated state, and
further comprising:
in a second electrically coupling operation, electrically coupling, by the system, the second RF port to the third RF port via controlling a fourth mechanical micro-actuator-based switch set to be in a second actuated state that electrically couples the second RF port to the third RF port.

17. A switch matrix, comprising:
a group of RF ports comprising a first port, a second port, a third port, and a fourth port;
respective mechanical micro-actuator-based switch sets comprising a respective first switch, a respective second switch, a respective third switch, a respective fourth switch, a respective fifth switch, and a respective sixth switch;
wherein the respective mechanical micro-actuator-based switch sets are controlled by respective applied voltage sets to at least one of:
set the respective sixth switch to a respective sixth actuated state to electrically couple the first RF port to the fourth RF port to obtain a first signal path;
set the respective third switch to a respective third actuated state to electrically couple the second RF port to the third RF port to obtain a second signal path;
set the respective first switch to a respective first actuated state and set the respective fourth switch to a respective fourth actuated state to electrically couple the first RF port to the third RF port to obtain a third signal path; or
set the respective second switch to a respective second actuated state and set the respective fifth switch to a respective fifth actuated state to electrically couple the second RF port to the fourth RF port to obtain a fourth signal path.

18. The switch matrix of claim 17, wherein the respective third switch comprises a first dual-membrane-cantilever switch device controlled by a respective third applied voltage set comprising a first voltage and a second voltage, and the respective sixth switch comprises a second dual-membrane-cantilever switch device controlled by a respective sixth applied voltage set comprising a third voltage and a fourth voltage.

19. The switch matrix of claim 17, wherein each of the first signal path, the second signal path, the third signal path and the fourth signal path comprises two of the respective mechanical micro-actuator-based switches, wherein the first signal path does not share a switch with the second signal path, the third signal path or the fourth signal path, wherein the second signal path does not share a switch with the third signal path or the fourth signal path, and wherein the third signal path does not share a switch with the fourth signal path.

20. The switch matrix of claim 17, wherein the first switch port is electrically coupled to the fourth switch port, and wherein the first switch and the fourth switch port are de-actuated to electrically decouple the first switch from the third switch port.
